(19) United States
(12) Patent Application Publication
(10) Pub. No.: US 2010/0101851 A1
(43) Pub. Date: Apr. 29, 2010

(54) WIRING SUBSTRATE AND METHOD OF MANUFACTURING THE SAME

(75) Inventors: Shigetsugu Muramatsu, Nagano (JP); Yasuhiko Kusama, Nagano (JP)

Correspondence Address: KRATZ, QUINTOS & HANSON, LLP, 1420 K Street, N.W., Suite 400, WASHINGTON, DC, 20005, US

(73) Assignee: SHINKO ELECTRIC INDUSTRIES CO., LTD., Nagano-shi (JP)

(21) Appl. No.: 12/606,538

(22) Filed: Oct. 27, 2009

(30) Foreign Application Priority Data
Oct. 27, 2008 (JP) 2008-275888

(51) Int. Cl. H05K 1/02; H05K 3/10

(52) U.S. Cl. 174/262; 29/846; 29/874

(57) ABSTRACT

A wiring substrate, includes a first wiring layer, an insulating layer formed on the first wiring layer, a via conductor filled to penetrate the insulating layer in a thickness direction and connected to a connection portion of the first wiring layer, and a second wiring layer which is formed on the insulating layer and whose connection portion is connected to the via conductor, wherein, out of the first wiring layer and the second wiring layer, the connection portion of one wiring layer is formed as a land whose diameter is larger than a diameter of the via conductor, and the connection portion of other wiring layer is formed as a landless wiring portion whose diameter is equal to or smaller than a diameter of the via conductor.

### CROSS-REFERENCE TO RELATED APPLICATIONS

This application is based on and claims priority of Japanese Patent Application No. 2008-275888 filed on Oct. 27, 2008, the entire contents of which are incorporated herein by reference.

### BACKGROUND OF THE INVENTION

1. Field of the Invention

The present invention relates to a wiring substrate including a multilayer wiring structure in which upper and lower wiring layers are connected via holes (via conductors) provided in an insulating layer, and a method of manufacturing the same.

2. Description of the Related Art

In the prior art, there is the wiring substrate employed to mount an electronic component such as a semiconductor chip. In such wiring substrate, the wiring layer and the insulating layer are stacked alternately, and the upper and lower wiring layers are connected electrically mutually via the via holes (via conductors) provided in the insulating layer.

In Patent Literature 1 (Patent Application Publication (KOKAI) Hei 9-199862), it is set forth that, in the multilayer printed wiring board in which two inner layer circuits and the outer layer circuits are connected via the non-penetrated connection holes, a wiring density is increased by employing such a structure that no land portion is formed on the inner layer circuits on the outer layer circuit side.

In Patent Literature 2 (Patent Application Publication (KOKAI) 2001-177243), it is set forth that the through holes are formed in the insulating layer being put between the upper and lower wiring substrates, and end portions of the wiring patterns of the upper and lower wiring substrates are connected electrically via the electrical connection portions filled in the through holes.

In Patent Literature 3 (Patent Application Publication (KOKAI) 2002-16334), it is set forth that, in the multilayer printed wiring substrate, the through holes are provided to intersect orthogonally with the outer layer circuits, the conductive paste is filled in the through holes, and a width of the outer layer circuit is formed smaller than a diameter of the through hole.

In Patent Literature 4 (Patent Application Publication (KOKAI) 2004-235331), it is set forth that, in the printed wiring substrate, the land of the high-density wiring portion being formed in the via hole is formed smaller in diameter than the window portion of the surface metallic foil which is provided in processing the non-penetrated holes for the via hole formation.

As explained in the column of related art described later, in the multilayer wiring substrate, normally the lands whose diameter is larger than the via hole are arranged in the portions of the wiring layers connected to the via holes such that the wiring layers of the upper and lower sides do not deviate from the via holes (via conductors) provided in the insulating layer.

In order to improve a wiring density, it constitutes an important factor how many wiring layers can be arranged in the area between the via holes. Since the land whose diameter is larger than a diameter of the via hole is arranged on each via hole, such a problem is caused that a width between the via holes on which the wiring layer can be arranged is narrowed due to the influence of the land and an improvement of a wiring density is prevented.

### SUMMARY OF THE INVENTION

It is an object of the present invention to provide a wiring substrate, which is capable of increasing a wiring density and also in which interlayer connection between upper and lower wiring layers are easily carried out, and a method of manufacturing the same.

The present invention is concerned with a wiring substrate, which includes a first wiring layer; an insulating layer formed on the first wiring layer; a via conductor filled to penetrate the insulating layer in a thickness direction, and connected to a connection portion of the first wiring layer; and a second wiring layer which is formed on the insulating layer and whose connection portion is connected to the via conductor; wherein, out of the first wiring layer and the second wiring layer, the connection portion of one wiring layer is formed as a land whose diameter is larger than a diameter of the via conductor, and the connection portion of other wiring layer is formed as a landless wiring portion whose diameter is equal to or smaller than a diameter of the via conductor.

In the present invention, out of a pair of first and second wiring layers located on the upper and lower sides and connected via the via conductor provided in the insulating layer, the connection portion of any one wiring layer is formed as the land portion whose diameter is larger than the via hole and is connected to the via conductor, while the connection portion of the other wiring layer is formed as the landless wiring portion whose diameter is equal to or smaller than the diameter of the via conductor and is connected to the via conductor.

In one mode of the present invention, the connection portion of the lower first wiring layer is formed as the land, and the connection portion of the upper second wiring layer is formed as the landless wiring portion. In the case of this mode, the second wiring layer further includes the land to carry out an interlayer connection to the upper wiring layer, on the insulating layer.

In the case that such wiring structure is formed, first, the via hole is formed in the insulating layer on the land of the first wiring layer by the laser. At this time, the diameter of the land is set larger than the via hole, and the land acts as the stopper of the laser. Also, the second wiring layer having the landless wiring portion, which is arranged on the via conductor that fills the via hole and whose diameter is equal to the via hole, is formed on the insulating layer.

Since the connection portion of the second wiring layer to the via conductor is formed as the landless wiring portion, the area where the wiring formation is possible between the via holes can be secured wider than the case where the land is arranged. Therefore, the number of wiring layers arranged in the area between the via holes can be increased, so that a wiring density can be improved.

Also, since the difficulty of process in forming the laser via on the landless wiring portion of the second wiring layer is high, the laser via is arranged on the land of the second wiring layer. Accordingly, a wiring density between the via holes can be improved, and also an interlayer connection by using the laser via can be formed easily.

Otherwise, the above wiring structure can be formed by providing upright the metal post without formation of the laser via.

Also, in one mode of the present invention, the connection portion of the lower first wiring layer is formed as the landless wiring portion, and the connection portion of the upper second wiring layer is formed as the land. In the case of this mode, the second wiring layer further includes the connection portion whose diameter is equal to or smaller than the via conductor, to carry out an interlayer connection to the upper wiring layer, on the insulating layer.

In the case that this wiring structure is formed, first, the metal post whose diameter is equal to or more than the connection portion is provided upright on the connection portion of the lower first wiring layer. Then, the metal post is embedded in the insulating layer, and the insulating layer is ground, thus the upper surface of the metal post is exposed and the insulating layer is left on the side the metal post. Then, the second wiring layer in which the land is arranged on the metal post is formed on the insulating layer.

Accordingly, the connection portion of the lower first wiring layer to the via conductor is formed as the landless wiring portion. Therefore, a wiring density in the area between the metal posts (via conductors) can be improved in contrast to the case where the land is arranged.

Also, the land whose diameter is larger than the metal post is arranged on the metal post. Therefore, an alignment accuracy of the photolithography in forming the second wiring layer can be relaxed, and the degree of difficulty of process can be lowered. Also, the second wiring layer includes separately a connection portion formed on the insulating layer in addition to the land, and the interlayer connection to the upper wiring layer is carried out by similarly providing upright the metal post to the connection portion.

As explained above, in the present invention, a wiring density can be increased in the area between the via holes, and also an interlayer connection between the upper and lower wiring layers can be easily carried out.

### BRIEF DESCRIPTION OF THE DRAWINGS

FIGS. 1A to 1D are sectional views (#1) showing a method of manufacturing a wiring substrate in the related art associated with the present invention;

FIGS. 2A to 2C are sectional views (#2) showing the method of manufacturing the wiring substrate in the related art associated with the present invention;

FIG. 3 is a perspective view showing a state of a connection via in the wiring substrate in the related art associated with the present invention;

FIG. 4 is a plan view showing an example of a design rule of the wiring substrate in the related art associated with the present invention;

FIGS. 5A to 5D are sectional views (#1) showing a method of manufacturing a wiring substrate according to a first embodiment of the present invention;

FIGS. 6A to 6C are sectional views (#2) showing the method of manufacturing the wiring substrate according to the first embodiment of the present invention;

FIGS. 7A to 7C are sectional views (#3) showing the method of manufacturing the wiring substrate according to the first embodiment of the present invention;

FIG. 8 is a perspective view showing a state of a connection via of the wiring substrate according to the first embodiment of the present invention;

FIG. 9 is a plan view showing an example of a design rule of the wiring substrate according to the first embodiment of the present invention;

FIGS. 10A to 10C are sectional views (#1) showing a method of manufacturing a wiring substrate according to a second embodiment of the present invention;

FIGS. 11A and 11D are sectional views (#2) showing the method of manufacturing the wiring substrate according to the second embodiment of the present invention; and

FIGS. 12A to 12D are sectional views (#3) showing the method of manufacturing the wiring substrate according to the second embodiment of the present invention;

FIGS. 13A to 13D are sectional views (#1) showing a method of manufacturing a wiring substrate according to a third embodiment of the present invention;

FIGS. 14A and 14C are sectional views (#2) showing the method of manufacturing the wiring substrate according to the third embodiment of the present invention;

FIGS. 15A to 15C are sectional views (#3) showing the method of manufacturing the wiring substrate according to the third embodiment of the present invention;

FIGS. 16A and 16B are sectional views (#4) showing the method of manufacturing the wiring substrate according to the third embodiment of the present invention; and

FIG. 17 is a perspective view showing a state of a connection via of the wiring substrate according to the third embodiment of the present invention.

### DETAILED DESCRIPTION OF THE PREFERRED EMBODIMENTS

Embodiments of the present invention will be explained with reference to the accompanying drawings hereinafter.

(Related Art)

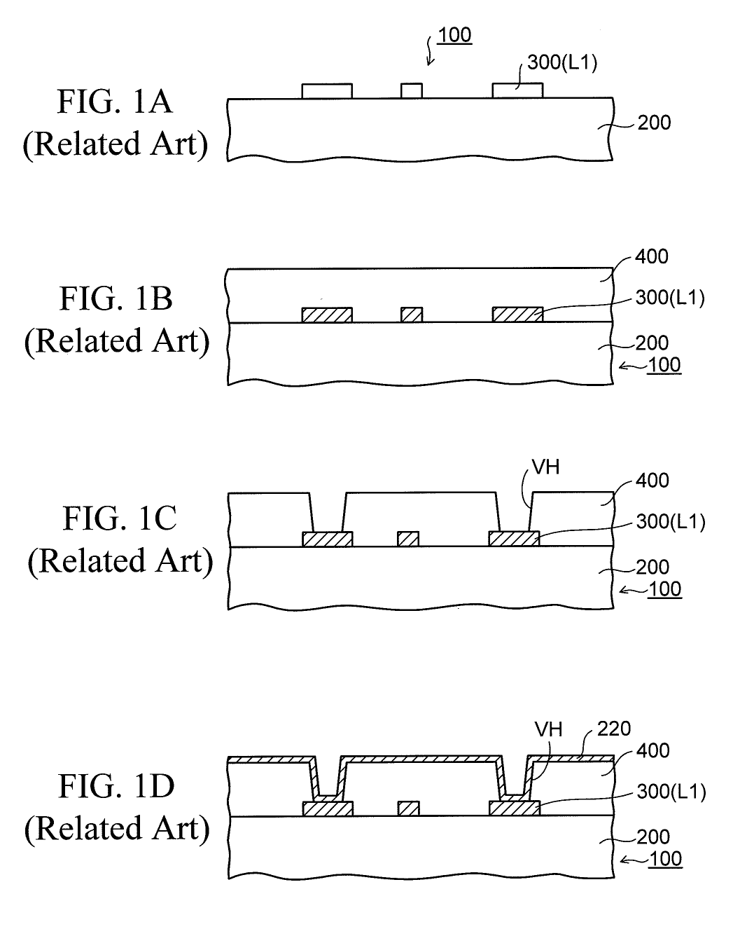

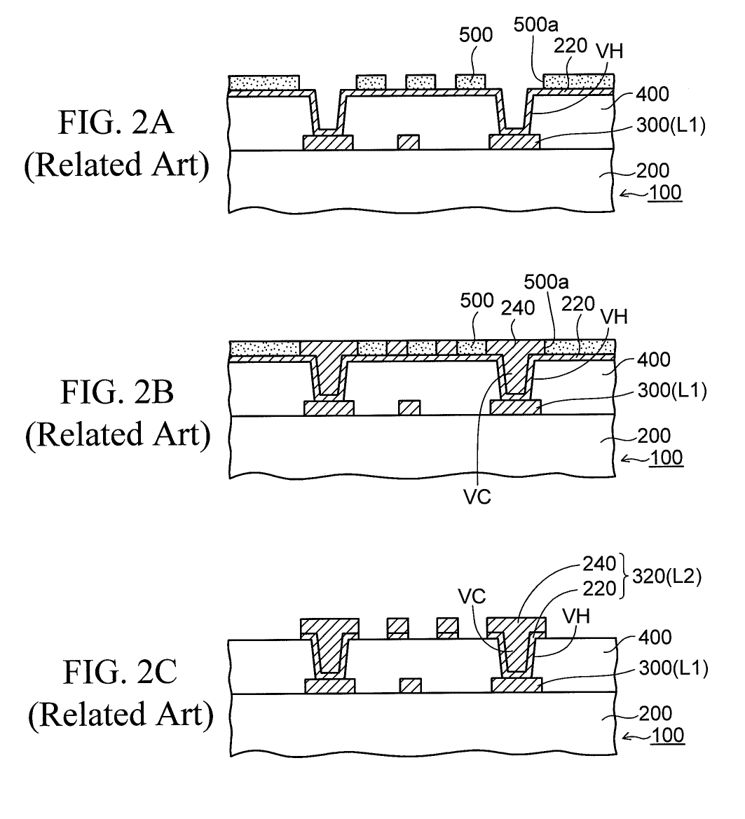

Prior to the explanation of a method of manufacturing a wiring substrate according to embodiments of the present invention, the problem of the related art associated with the present invention will be explained hereunder. FIGS. 1A to 1D and FIGS. 2A to 2C are sectional views showing a method of manufacturing a wiring substrate in the related art.

As shown in FIG. 1A, in the method of manufacturing the wiring substrate in the related art, first, a base wiring plate 100 in which a first wiring layer 300 is formed on an insulating core substrate 200 is prepared.

Although not particularly illustrated, in the base wiring plate 100, the first wiring layer 300 is formed on both surface sides of the core substrate 200, and the first wiring layer 300 on both surface sides is mutually connected via the through electrodes passing through the core substrate 200. A build-up wiring is formed on both surface sides of the base wiring plate 100. In this case, such a situation will be explained hereunder that a multilayer wiring is formed on the upper surface side of the base wiring plate 100.

In FIG. 1A, lands L1 of the first wiring layer 300 are shown. The land L1 acts as a stopper when via holes are formed in an interlayer insulating layer formed on the first wiring layer 300 by the laser. This is because, when the laser is misaligned and protrudes from the first wiring layer 300, the underlying core substrate 200 is processed and thus the normal via hole cannot be obtained.

Therefore, a diameter of the land 1 is set larger than a diameter of the via hole such that, even when the laser is misaligned, the via hole does not protrude from the land L1.

Then, as shown in FIG. 1B, an interlayer insulating layer 400 for covering the first wiring layer 300 is formed by pressure-bonding a resin film on the base wiring plate 100. Then, as shown in FIG. 1C, via holes VH each reaching the land L1 of the first wiring layer 300 are formed by processing the interlayer insulating layer 400 by means of the laser. As described above, the diameter of the via hole VH is set to the diameter not to protrude from the land L1 even though the laser is misaligned, so that the via hole VH can be formed stably in the area of the land L1.

Then, as shown in FIG. 1D, a seed layer 220 is formed on the interlayer insulating layer 400 and on inner surfaces of the via holes VH. After this, as shown in FIG. 2A, a plating resist 500 in which opening portions 500a are provided in portions where a second wiring layer is formed is formed. At this time, the opening portion 500a, a diameter of which is larger than the via hole VH, of the plating resist 500 is arranged on the via hole VH such that the second wiring layer does not deviate from the via hole VH.

Then, as shown in FIG. 2B, a metal plating layer 240 is formed in the opening portions 500a of the plating resist 500 and the via holes VH by the electroplating utilizing the seed layer 220 as a plating power feeding path. In the via holes VH, the plating is applied to the inner side from the seed layer 220, and a via conductor VC is filled in the via hole VH.

Then, as shown in FIG. 2C, the plating resist 500 is removed. Then, the seed layer 220 is etched. Accordingly, a second wiring layer 320 constructed by the seed layer 220 and the metal plating layer 240 is formed on the interlayer insulating layers 400. The second wiring layer 320 is formed to contain the via conductor VC in the via hole VH, and is connected to the land L1 of the first wiring layer 300 via the via conductor VC.

At this time, a land L2 of the second wiring layer 320 is arranged on the via hole VH (via conductor VC). A diameter of the land L2 is set larger than the diameter of the via hole VH (via conductor VC) such that the second wiring layer 320 does not deviate from the via hole VH. In this case, when the via hole is formed on the land L2 of the second wiring layer 320 by the laser, the via hole can be formed stably with such a situation that the laser does not protrude from the land L2.

Subsequently, a desired multilayer wiring is formed on the base wiring plate 100 by repeating the similar steps.

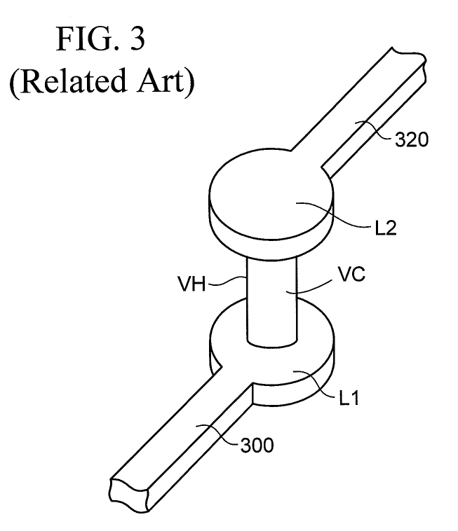

In this manner, in the related art, as shown in a perspective view of FIG. 3, the lands L1, L2, a diameter of which is larger than the diameter of the via conductor VC, are arranged to the upper and lower sides of the via conductor VC in the via hole VH respectively. The first and second wiring layers 300, 320 are connected to the via conductor VC via the lands L1, L2.

As a result, even though the positions and the diameters between the via hole VH and the lands L1, L2 of the upper and lower sides are varied in the manufacturing steps, the first wiring layer 300 and the second wiring layer 320 do not deviate from the via conductor VC and can be stably connected electrically.

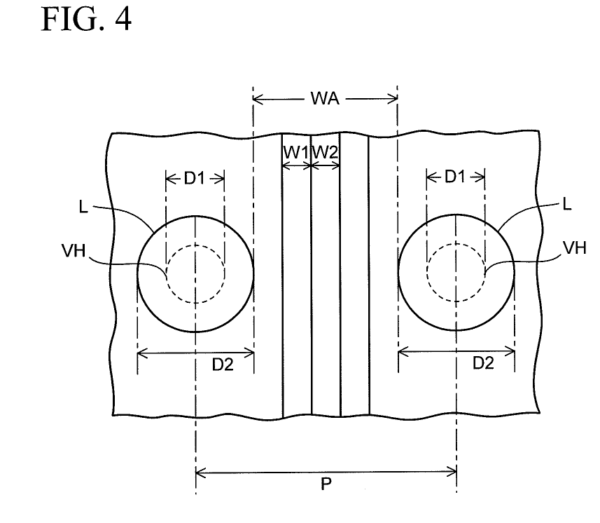

In FIG. 4, an example of the design rule applied when the land is provided to the wiring layer is shown. As shown in FIG. 4, the case where a diameter D1 of the via hole VH is 50 μm, a pitch P between the via holes VH is 225 μm, and a diameter D2 of the land L is 100 μm will be explained hereunder. In this case, a width WA between the lands L is given by the pitch P between the via holes VH (225 μm)−a radius of the land L×2(100 μm)=125 μm.

Therefore, when the wiring layer in which line (wiring width) W1: space (hole width) W2 is 25 μm: 25 μm is formed, the number of wiring layers that can be arranged in the width WA between the lands L is 2.

Recently, with higher performance of a semiconductor device (LSI chip), a higher density of the wiring substrate on which the semiconductor device is mounted is requested. Therefore, a larger number of wiring layers must be arranged in the area between the via holes VH.

In FIG. 4, the area between the via holes VH in which the wiring layer can be arranged is narrowed because of the arrangement of the land L. Therefore, in order to increase the number of the wiring layers, the pitch of the line: space of the wiring layers must be made narrower.

However, the fine patterning of the wiring layer largely depends on the technology of photolithography. Therefore, a huge development cost is needed, and also the degree of difficulty of the process is increased. As a result, such a problem exists that the fine patterning of the wiring layer cannot be easily responded.

With the above, in order to improve a wiring density of the wiring substrate, it is important that a size of the land L should be formed as small as possible. As the result of the earnest study of the inventor of this application in view of the above problem, the inventor of this application has invented such a wiring structure that, out of the connection portions of wiring layers of the upper and lower sides connected to the via hole (via conductor), any one connection portion is formed as the land portion larger than the via hole while the other connection portion is formed as the landless wiring portion whose diameter is equal to or smaller than the diameter of the via hole.

### First Embodiment

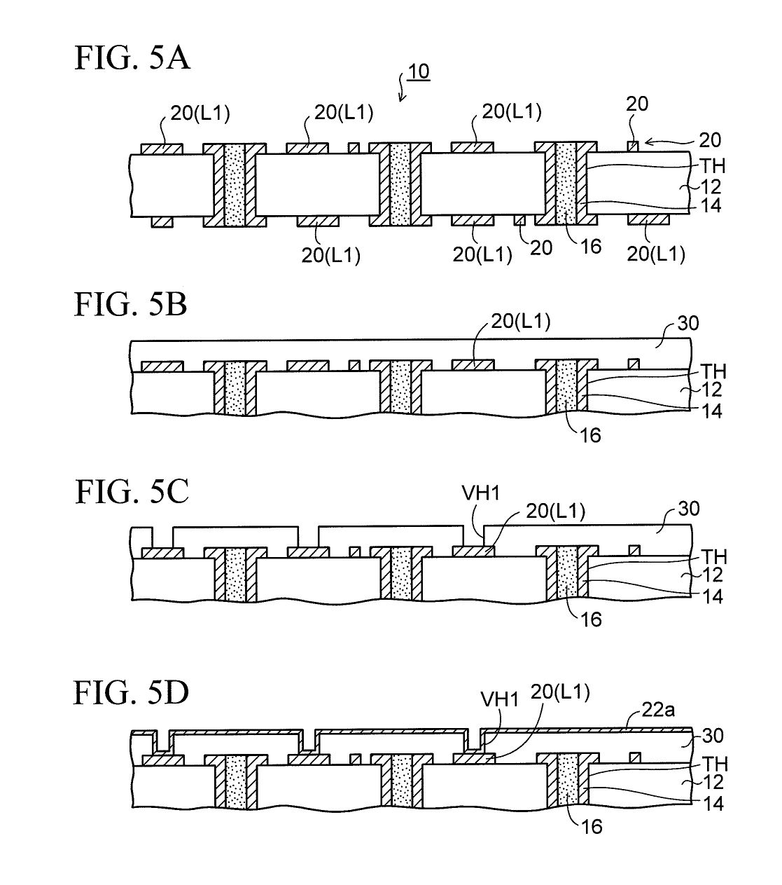

FIG. 5A to FIG. 7C are sectional views showing a method of manufacturing a wiring substrate according to a first embodiment of the present invention. In the method of manufacturing the wiring substrate according to the first embodiment, first, a base wiring plate 10 as shown in FIG. 5A is prepared. In the base wiring plate 10, through holes TH are provided in a core substrate 12, and a through hole plating layer 14 is formed in inner walls of the through holes TH respectively. A resin 16 is filled in the remained holes of the through holes TH.

Then, a first wiring layer 20 connected mutually via the through hole plating layer 14 is formed on both surface sides of the core substrate respectively. The first wiring layer 20 has lands L1 (also called the “connection pads” hereinafter), and the land L acts as the stopper when the via hole is formed in the interlayer insulating layer formed on the first wiring layer 20 by the laser. Even when the laser is misaligned, the diameter of the land L1 is set larger than the diameter of the via hole such that the via hole does not protrude from the land L1.

A build-up wiring is formed on both surface sides of the base wiring plate 10. In the following steps, in order to facilitate the explanation, a state that the build-up wiring is formed on the upper surface side of the base wiring plate 10 will be explained in the following steps.

Then, as shown in FIG. 5B, a first interlayer insulating layer 30 for covering the first wiring layer 20 is formed by pressure-bonding a resin film on the base wiring plate 10. Then, as shown in FIG. 5C, first via holes VH1 whose depth reaches the land L1 of the first wiring layer 20 are formed by processing the first interlayer insulating layer 30 by means of the laser.

At this time, as described above, the diameter of the land L1 is set larger than the diameter of the first via hole VH1. Therefore, the first via hole VH1 never protrudes from the land L1, and formed stably in the area.

Then, as shown in FIG. 5D, a seed layer 22a made of copper, or the like, is formed on the first interlayer insulating layer 30 and inner surfaces of the first via holes VH1 by the electroless plating.

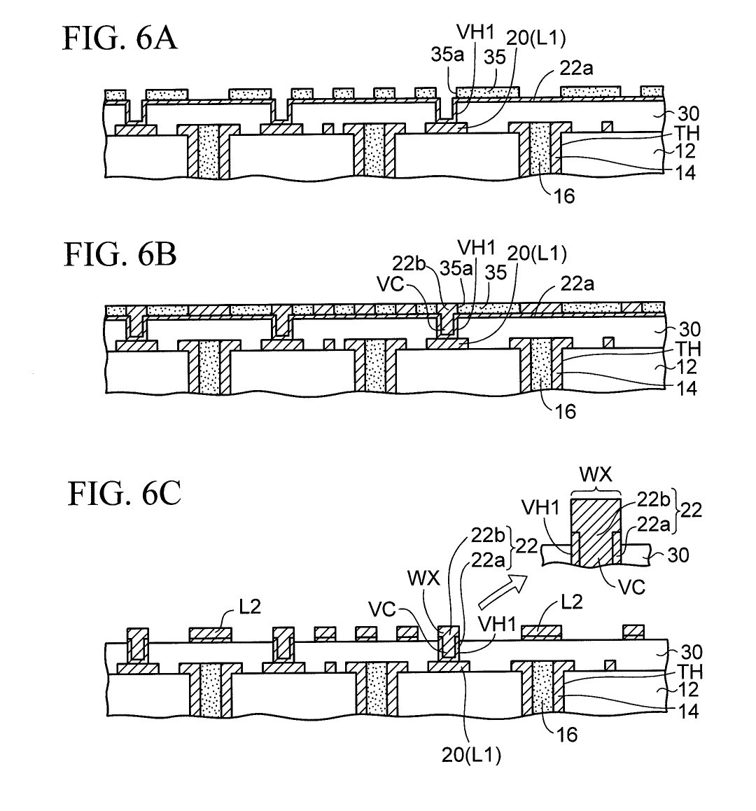

Then, as shown in FIG. 6A, a plating resist 35 in which opening portions 35a are provided in the portions where the second wiring layer is formed is formed on the seed layer 22a. At this time, on the first via hole VH1, the opening portion 35a of the plating resist 35 is formed with the identical diameter to the first via hole VH1.

Then, as shown in FIG. 6B, a metal plating layer 22b made of copper, or the like is formed to be filled in the opening portions 35a of the plating resist 35 containing the inner areas of the first via holes VH1 by the electroplating utilizing the seed layer 22a as a plating power feeding path. In the first via holes VH1, the plating is applied to the inner sides of the first via holes VH1 from the seed layer 22a, and a via conductor VC is filled in the first via hole VH.

Then, as shown in FIG. 6C, the plating resist 35 is removed. Then, the seed layer 22a is etched. Accordingly, a second wiring layer 22 constructed by the seed layer 22a and the metal plating layer 22b is obtained. In this manner, the second wiring layer 22 is formed by the semi-additive process.

The via conductor VC is filled in the first via holes VH1 arranged on the lands L1 of the first wiring layer 20, and landless wiring portions WX having the identical diameter with the via conductor VC are formed thereon to project from the upper surface of the first interlayer insulating layer 30.

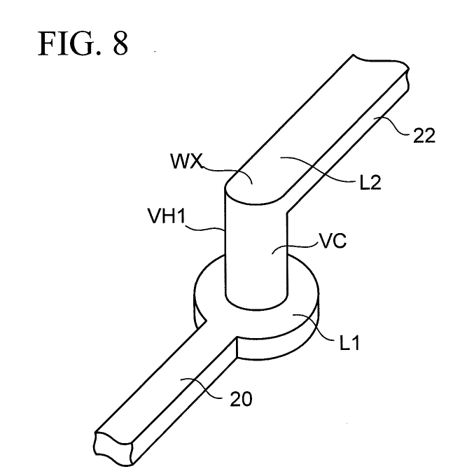

That is, by reference to FIG. 6C together with a perspective view of FIG. 8, the first wiring layer 20 on the lower side is connected to the via conductor VC via the land L1 whose diameter is larger than the first via hole VH1, and the second wiring layer 22 on the upper side is connected to the via conductor VC via the landless wiring portion WX whose diameter is equal to the diameter of the first via hole VH1.

In this case, in FIG. 8, a shape of the via conductor VC (first via hole VH1) is formed as a straight shape, but may be formed as a taper shape whose diameter is decreased gradually from the upper part to the lower part. When the via conductor VC (first via hole VH1) has a taper shape, the diameter of the land L1 of the first wiring layer 20 is set larger than a diameter of the bottom end surface of the via conductor VC (first via hole VH1), and the diameter of the landless wiring portion WX of the second wiring layer 22 is set equal to a diameter of the top end surface of the via conductor VC (first via hole VH1).

In second and third embodiments described later, when the via conductor (via hole) has a taper shape similarly, a diameter of the connection portion of the lower wiring layer is set based on a diameter of the bottom end surface of the via conductor (via hole) as a comparison reference and also a diameter of the connection portion of the upper wiring layer is set based on a diameter of the top end surface of the via conductor (via hole) as a comparison reference.

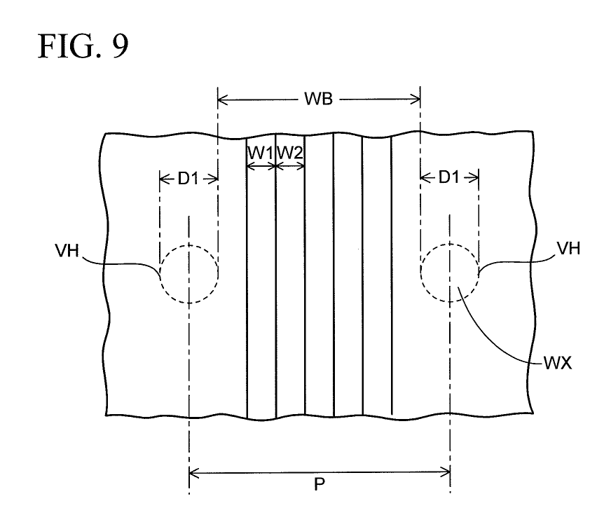

In the case where such wiring structure is employed, by reference to FIG. 9, the number of the second wiring layer 22 that can be arranged in the area between the via holes VH is compared under the same design rule in FIG. 4 in the related art. In FIG. 9, the illustration of the wiring layer connected to the landless wiring portion WX is omitted.

As shown in FIG. 9, in the present embodiment, the connection portion of the second wiring layer 22 of the upper side is formed as the landless wiring portion WX whose diameter is identical with the via holes VH. Therefore, a width WB between the via holes VH in which the wiring layer can be arranged is given by the pitch P between the via holes VH (225 μm)−a radius of the via holes VH×2 (50 μm)=175 μm.

Accordingly, like the related art, when the wiring layer in which line (wiring width) W1: space (hole width) W2 is 25 μm: 25 μm is formed, the number of wiring layers that can be arranged in the width WB between the via holes VH is increased to 3.

In this manner, since the connection portion of the second wiring layer 22 to the via conductor VC is formed as the landless wiring portion WX, the width WB between the via holes VH can be set wider than that in the related art under the same design rule. Therefore, a larger number of wiring layers can be arranged in the area between the via holes VH, so that a wiring density can be improved rather than the related art.

Otherwise, in the case that two wiring layers are formed in the area between the via holes VH like the related art, also the line: space of the wiring layer can be made thick by the amount produced when the width between the via holes VH is widened. Accordingly, the degree of difficulty of process can be lowered. Therefore, the highly reliable wiring layer can be formed with good yield without strict step management.

Then, returning to FIG. 6C, the explanation of the manufacturing method is continued. That is, the second wiring layer 22 is formed to have a land L2 in addition to the landless wiring portion WX mentioned above and arranged on the first via hole VH1. The land L2 has a larger diameter than the first via hole VH1, and is formed on the first wiring layer 30.

In the present embodiment, the multilayer wiring is built up by forming the via hole by means of the laser, so that the degree of difficulty of process can be lowered if the land L2 acting as the stopper for the laser is also provided on the second wiring layer 22.

Unlike the present embodiment, when all connection portions of the second wiring layer 22 are formed as the landless wiring portion whose diameter is equal to the via hole, it is extremely difficult to form the via hole by the laser.

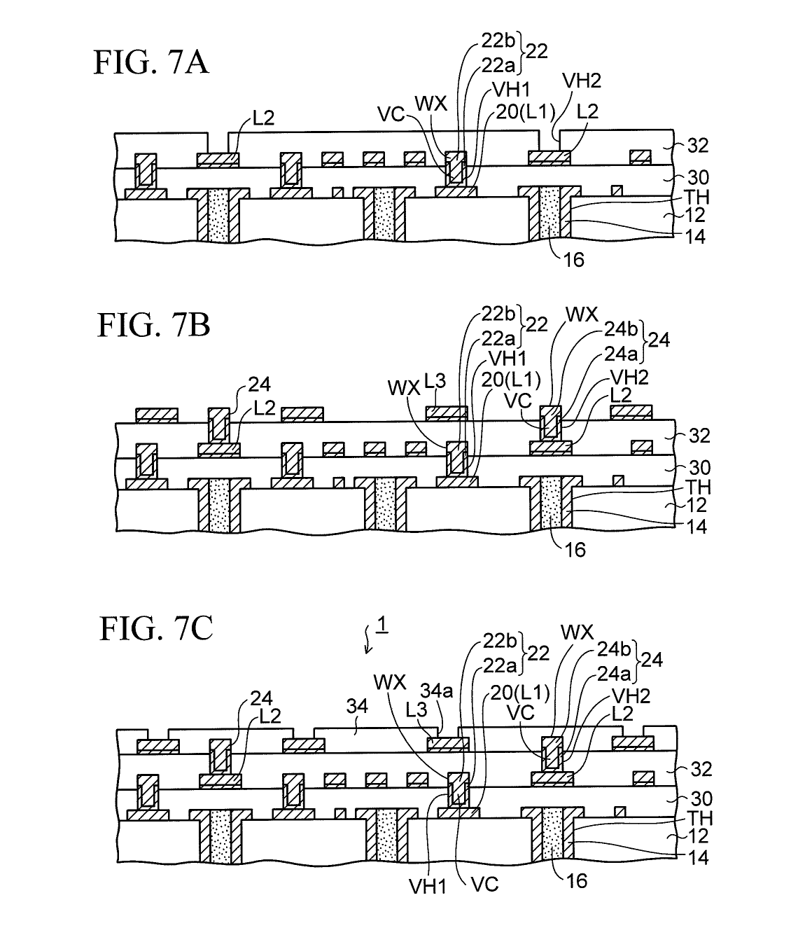

Then, as shown in FIG. 7A, a second interlayer insulating layer 32 is formed on the second wiring layer 22. Then, the second via holes VH whose depth reaches the land L2 of the second wiring layer 22 are formed by processing the second interlayer insulating layer 32 by means of the laser. At this time also, the second via hole VH is formed on the land L2 whose diameter is larger than that of the second via hole VH, and therefore the second via hole VH never protrudes from the land L2 and can be formed with good reliability.

Then, as shown in FIG. 7B, a third wiring layer constructed by a seed layer 24a and a metal plating layer 24b are formed on the second interlayer insulating layer 32 by repeating the above steps in FIG. 5D to FIG. 6C. Like the second wiring layer 22, the third wiring layer 24 is formed to contain the landless wiring portion WX that is formed on the via conductor VC in the second via hole VH2 and also a land L3 that is formed on the second interlayer insulating layer 32.

Then, as shown in FIG. 7C, a solder resist 34 in which an opening portion 34a is provided on the lands L3 of the third wiring layer 24 is formed. Then, a contact layer (not shown) is formed by forming Ni/Au plating layers on the land L3 of the third wiring layer 24, or the like.

With the above, a wiring substrate 1 of the first embodiment can be obtained. In the present embodiment, the build-up wiring having such a wiring structure that the land is arranged to lower side of the via conductor (via hole) and the landless wiring portion is arranged to upper side of the via conductor is also formed on the lower surface side of the base wiring plate 10. Also, the number of the stacked wiring layers formed on both surface sides of the base wiring plate 10 may be set arbitrarily.

In the wiring substrate 1 of the first embodiment, as shown in FIG. 7C, the first interlayer insulating layer 30 is formed on the base wiring plate 10 which has the first wiring layer 20 containing the lands L1. The first via holes VH1 reaching the land L1 are formed in the first interlayer insulating layer 30. The diameter of the land L1 of the first wiring layer 20 is set larger than the diameter of the first via hole VH1.

By reference to FIG. 7C together with a perspective view of FIG. 8, the via conductor VC is filled in the first via hole VH1, and the via conductor VC is connected to the second wiring layer formed on the first interlayer insulating layer 30. Also, the connection portion of the second wiring layer 22 to the via conductor VC constitutes the landless wiring portion WX, and the landless wiring portion WX is set to the identical diameter with the via conductor VC (first via hole VH1).

The second wiring layer 22 is formed to contain the land L2 acting as the stopper for the laser in addition to the landless wiring portion WX. Also, the second interlayer insulating layer 32 is formed on the second wiring layer 22, and the second via holes VH2 reaching the land L2 are formed in the second interlayer insulating layer 32 by the laser.

Also, similarly, the via conductor VC is filled in the second via holes VH2, and the landless wiring portion WX of the third wiring layer 24 is connected to the via conductor VC. Also, the third wiring layer 24 is formed to have the land L3 in addition to the landless wiring portion WX.

Also, the solder resist 34 in which the opening portion 34a are provided on the land L3 of the third wiring layer 24 is formed.

In this manner, in the wiring substrate 1 of the first embodiment, out of a pair of the wiring layers of the upper and lower sides connected to the via hole (via conductor), the connection portion of the wiring layer of the lower side is formed as the land portion whose diameter is larger than the via hole and is connected to the via conductor while the connection portion of the wiring layer of the upper side is formed as the landless wiring portion whose diameter is equal to the diameter of the via hole and is connected to the via conductor.

Since such wiring structure is employed, as explained in FIG. 9, the width between the via holes in which the landless wiring portions are arranged can be secured wider than the case where the lands are arranged. Therefore, the number of wiring layers arranged in the area between the via holes can be increased, so that a wiring density can be improved rather than the related art.

Also, since the degree of difficulty of process in forming the via holes on the landless wiring portions by the laser is high, the wiring layers having the landless wiring portions have separately the lands on which the laser via is arranged respectively. As a result, a wiring density between the via holes can be improved, and also the formation of the interlayer connection by using the laser via can be facilitated.

### Second Embodiment

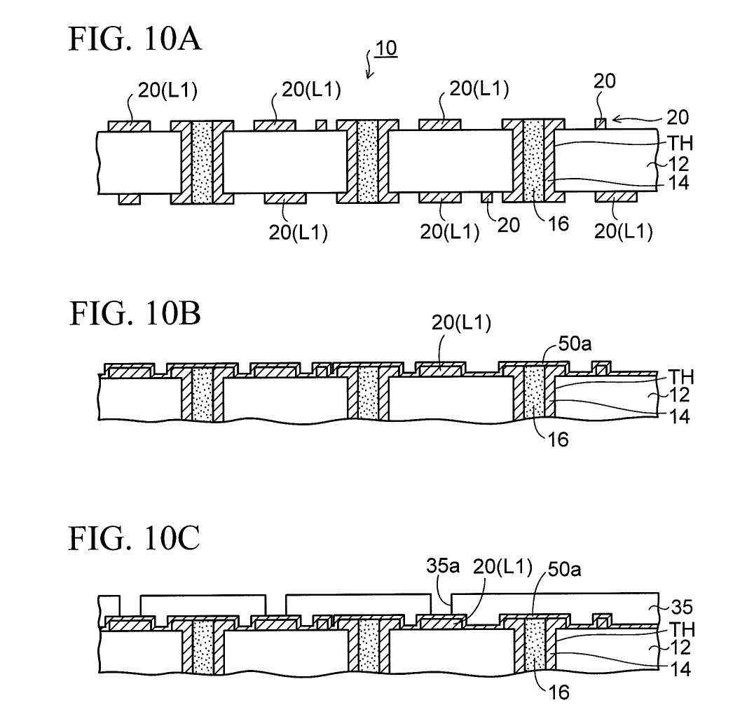

FIG. 10A to FIG. 12D are sectional views showing a method of manufacturing a wiring substrate according to a second embodiment of the present invention. In the above first embodiment, in steps in FIG. 6A, the diameter of the opening portion 35a in the plating resist 35 must be set equal to the diameter of the via hole VH. Therefore, it is feared that the misalignment becomes a problem depending on the performance of the employed exposure equipment. When the misalignment is caused beyond a tolerance, in some cases the hole may be still left in the via hole VH in forming the landless wiring portion WX.

A feature of the second embodiment resides in that the landless wiring portion is formed based on the metal post that is provided upright. In the second embodiment, explanation of the same steps as those in the first embodiment will be omitted herein.

In the second embodiment, as shown in FIG. 10A, the same base wiring plate 10 as that in FIG. 5A of the first embodiment is prepared. Then, as shown in FIG. 10B, a seed layer 50a for coating the first wiring layer 20 is formed on the base wiring plate 10.

Then, as shown in FIG. 10C, the plating resist 35 in which the column-like opening portions 35a are provided on the lands L1 of the first wiring layer 20 is formed. The opening portion 35a of the plating resist 35 is set to have the smaller diameter than the land L1. Accordingly, even when the opening portion 35a is misaligned in formation, such situation can be obtained that opening portion 35a does not deviate from the land L1.

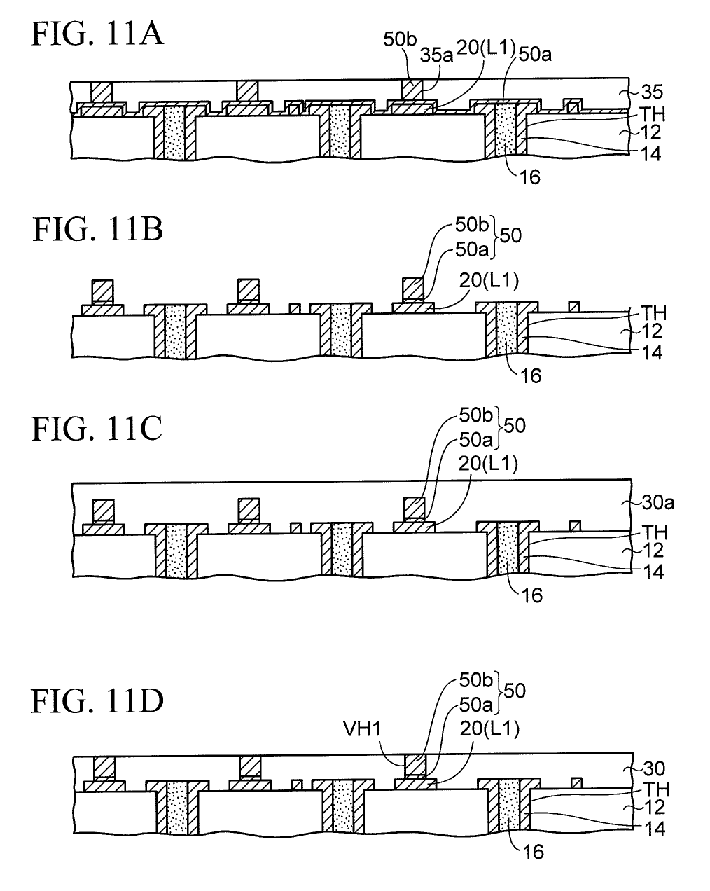

Then, as shown in FIG. 11A, a metal plating layer 50b made of copper, or the like is formed in the opening portions 35a of the plating resist 35 by the electroplating utilizing the seed layer 50a as a plating power feeding path.

Then, as shown in FIG. 11B, the plating resist 35 is removed. The seed layer 50a is etched by using the metal plating layer 50b as a mask. Thus, a first metal post (column) 50 constructed by the seed layer 50a and the metal plating layer 50b is obtained on the lands L1 of the first wiring layer 20. The underlying first wiring layer 20 is slightly etched in etching the seed layer 50a, but a problem does not arise particularly since a film thickness of the seed layer 50a is considerably thin in contrast to the first wiring layer 20.

Then, as shown in FIG. 11C, a resin film is pressure-bonded onto a structure in FIG. 11B. Thus, the whole of the first metal post 50 is embedded in a resin layer 30a (insulating layer).

Then, as shown in FIG. 11D, the resin layer 30a is ground by the sand blast method, or the like until the upper surfaces of the first metal posts 50 is exposed. Accordingly, the resin layer 30a is left on the side of the first metal posts 50 and the first interlayer insulating layer 30 is obtained. As a result, the first via holes VH1 are formed substantially in the first interlayer insulating layer 30, and the first metal posts 50 is filled in the first via holes VH1 to constitute the via conductors.

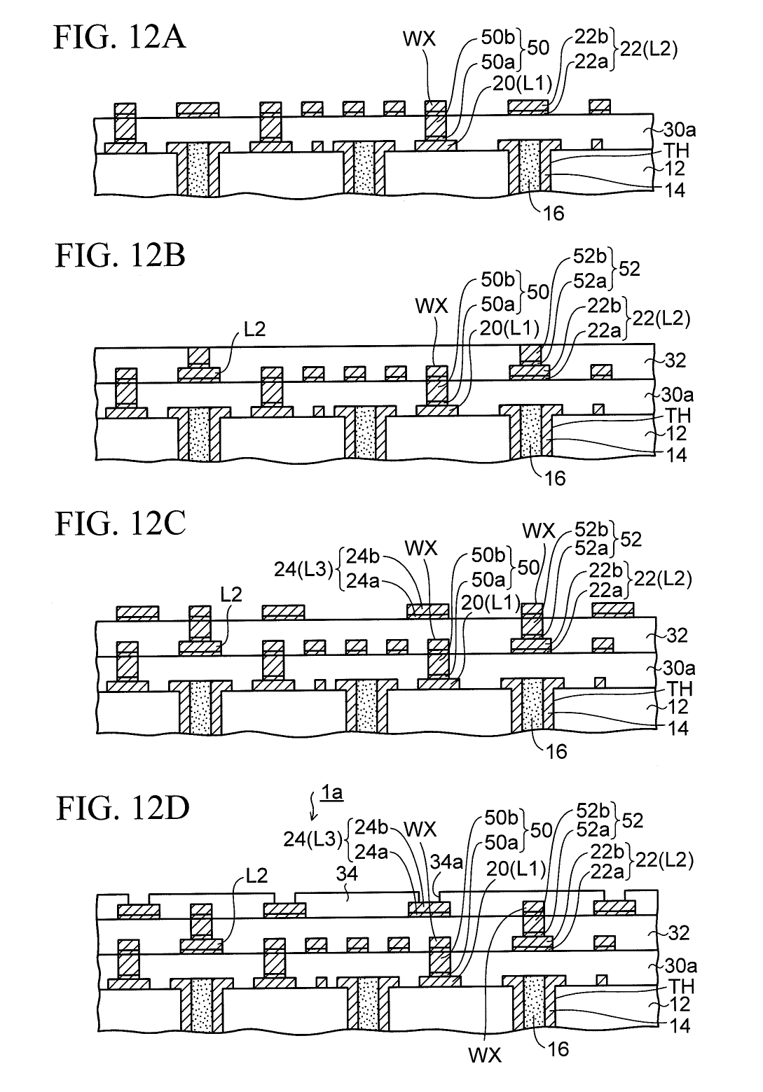

Then, as shown in FIG. 12A, the second wiring layer 22 constructed by the seed layer 22a and the metal plating layer 22b is formed on the first interlayer insulating layer 30 by the semi-additive process. The second wiring layer 22 is formed to contain the landless wiring portion WX which is arranged on the first metal post 50 to have the identical diameter with the first metal post 50, and the land L2 which is arranged on the first interlayer insulating layer 30.

In the second embodiment, upon forming the landless wiring portions WX by the semi-additive process, the opening portion in the plating resist must be arranged on the first metal post 50. In this case, the disadvantage caused due to the misalignment is hard to occur rather than the first embodiment. This is because, since the first metal post 50 is filled under the opening portion of the plating resist, such a problem does not arise that the hole still remains even though the opening portion is slightly misaligned from the first metal post 50.

Therefore, in the second embodiment, the first metal post 50 is formed, and then the landless wiring portion WX of the second wiring layer 22 is arranged thereon. Thus, the diameter of the landless wiring portion WX can be set equal to or smaller than the diameter of the first metal post 50 (via conductor).

Accordingly, like FIG. 6C explained in the first embodiment, the connection portion of the first wiring layer 20 connected to the bottom portion of the first metal post 50 (via conductor) is formed as the land L1 whose diameter is larger than the first metal post 50. In contrast, the connection portion of the second wiring layer 22 connected to the top portion of the first metal post 50 (via conductor) is formed as the landless wiring portion WX whose diameter is equal to or smaller than the first metal post 50.

Then, as shown in FIG. 12B, the above steps in FIG. 11B to FIG. 11D are repeated. Accordingly, second metal posts 52 constructed by a seed layer 52a and a metal plating layer 52b are formed on the lands L2 of the second wiring layer 22, and the second interlayer insulating layer 32 is formed on the side of the second metal posts 52.

Then, as shown in FIG. 12C, like above FIG. 12A, the landless wiring portions WX arranged on the second metal posts 52 to have the identical diameter with it and the third wiring layer 24 arranged on the second interlayer insulating layers 32 to contain the land L3 are formed by the semi-additive process. Similarly, the third wiring layer 24 is constructed by the seed layer 24a and the metal plating layer 24b.

Here, in the second embodiment, the stack via can be formed by arranging the second metal post 52 on the landless wiring portion WX of the second wiring layer 22.

Then, as shown in FIG. 12D, the solder resist 34 in which the opening portions 34a are provided on the lands L3 of the third wiring layer 24 is formed. Also, the contact layer (not shown) is formed by forming the Ni/Au plating layer, or the like, on the lands L3 of the third wiring layer 24.

As a result, a wiring substrate 1a having the substantially same structure as that in FIG. 7C can be obtained. In the second embodiment also, the build-up wiring is formed on the lower surface side of the base wiring plate 10, and the number of stacked layers can be set arbitrarily.

In the second embodiment, the similar advantages to those in the first embodiment can be achieved. In addition, in the second embodiment, the metal posts 50, 52 are formed to stand upright as the via conductor, and then the landless wiring portions WX are formed thereon. As a result, an alignment accuracy of the photolithography applied to form the landless wiring portions WX can be relaxed, so that the wiring substrate can be manufactured at a low cost with good yield.

### Third Embodiment

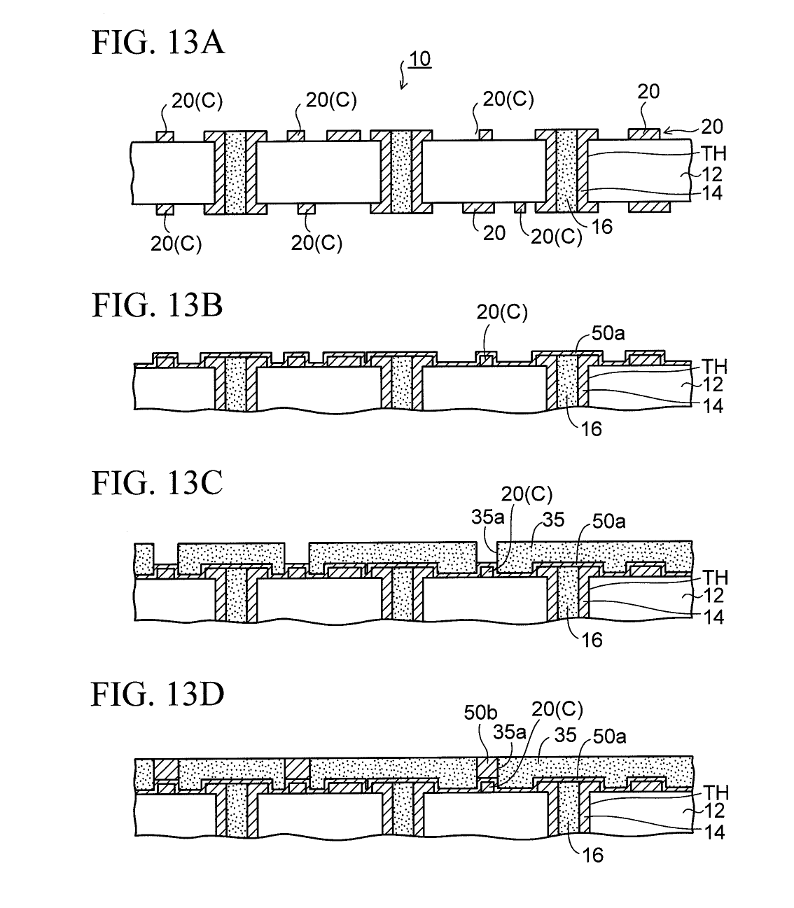

FIG. 13A to FIG. 16B are sectional views showing a method of manufacturing a wiring substrate according to a third embodiment of the present invention. In the foregoing first and second embodiments, out of the connection portions of the first wiring layer and the second wiring layer connected to the via hole (via conductor), the connection portion of the first wiring layer on the lower side is formed as the land, and the connection portion of the second wiring layer on the upper side is formed as the landless wiring portion.

In the third embodiment, conversely the connection portion of the first wiring layer on the lower side is formed as the landless wiring portion, and the connection portion of the second wiring layer on the upper side is formed as the land.

In the method of manufacturing the wiring substrate according to the third embodiment, as shown in FIG. 13A, first, the base wiring plate 10 similar to that in FIG. 5A of the first embodiment is prepared. In the third embodiment, since no land is provided to the lower wiring layer, the first wiring layer 20 of the base wiring plate 10 has a post connection portion C whose diameter is equal to or smaller than the via conductor (metal post), and does not have the land. The post connection portion C of the first wiring layer 20 constitutes a main portion of the landless wiring portion.

Then, as shown in FIG. 13B, the seed layer 50a for covering the first wiring layer 20 is formed the base wiring plate 10. Then, as shown in FIG. 13C, the plating resist 35 in which the column-like opening portions 35a are provided on the post connection portions C of the first wiring layer 20 is formed. The diameter of the opening portion 35a of the plating resist 35 is set to a diameter that is equal to or larger than the diameter of the post connection portion C.

Then, as shown in FIG. 13D, the metal plating layer 50b is formed in the opening portions 35a of the plating resist 35 by the electroplating utilizing the seed layer 50a as a plating power feeding path.

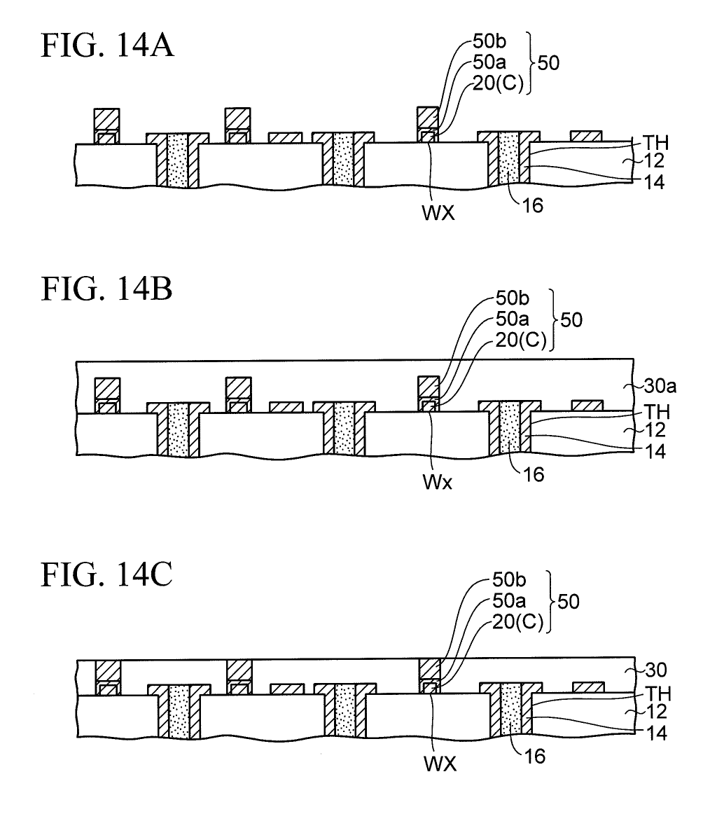

Then, as shown in FIG. 14A, the plating resist 35 is removed. Then, the seed layer 50a is etched.

Accordingly, the first metal posts 50 constructed by the post connection portion C of the first wiring layer 20, the seed layer 50a, and the metal plating layer 50b are formed. The first metal posts 50 are formed with the straight shape on the base wiring plate 10. Therefore, the post connection portion C of the first wiring layer 20 arranged to the lower portion of the first metal post 50 is formed as the landless wiring portion WX whose diameter is equal to the first metal posts 50.

Then, as shown in FIG. 14B, the resin layer 30a (insulating layer) in which the whole of the first metal posts 50 are embedded is formed on the base wiring plate 10. Then, as shown in FIG. 14C, the resin layer 30a is ground by the sand blast method, or the like until the upper surfaces of the first metal posts 50 is exposed. Accordingly, the resin layer 30a is left on the side of the first metal posts 50, and the first interlayer insulating layer 30 can be obtained.

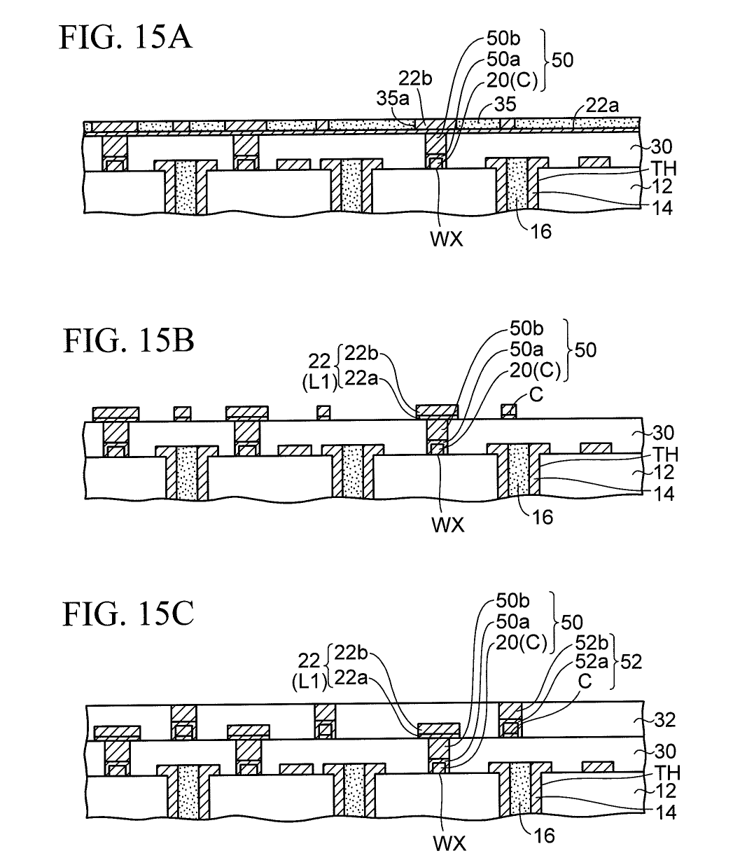

Then, as shown in FIG. 15A, the seed layer 22a is formed on the first interlayer insulating layer and the first metal posts 50, and then the plating resist 35 in which the opening portions 35a are provided in the portions where the second wiring layer is formed is formed. Then, the metal plating layer 22b is formed in the opening portions 35a of the plating resist 35 by the electroplating utilizing the seed layer 22a as a plating power feeding path.

Then, as shown in FIG. 15B, the plating resist is removed. Then, the seed layer 22a is etched by using the metal plating layer 22b as a mask. Thus, the second wiring layer 22 constructed by the seed layer 22a and the metal plating layer 22b are formed.

The second wiring layer 22 is formed to contain the land L1 arranged on the first metal post 50, and the post connection portion C arranged on the first interlayer insulating layer 30. The land L1 of the second wiring layer 22 is formed to have a diameter that is larger than the first metal post 50, and the post connection portion C is formed to have a diameter that is equal to or smaller than the first metal post 50.

By forming the land L1 whose diameter is larger than the first metal post 50 on the first metal post 50, an alignment accuracy of the photolithography can be relaxed. Therefore, unless the high-performance exposure equipment is employed, it is not feared that the second wiring layer 22 deviates from the first metal post 50, so that the degree of difficulty of process can be lowered.

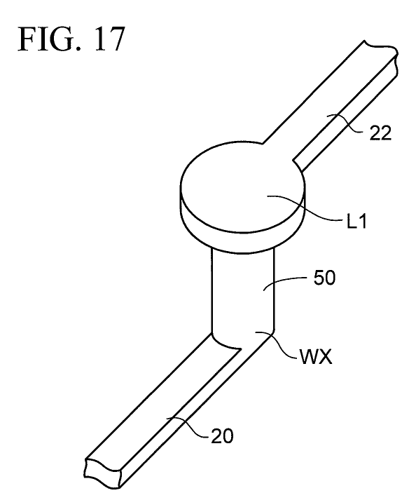

By reference to FIG. 15B together with a perspective view of FIG. 17, the first wiring layer 20 on the lower side is connected to the first metal post 50 via the landless wiring portion WX whose diameter is equal to the first metal post 50, and the second wiring layer 22 on the upper side is connected to the first metal post 50 via the land L1 whose diameter is larger than the first metal post 50.

Returning to FIG. 15C, the explanation of the manufacturing method is continued. The steps from FIG. 13A to FIG. 14C are applied repeatedly to the structure in FIG. 15B. Accordingly, the second metal posts 52 constructed by the post connection portion C of the second wiring layer 22, the seed layer 52a, and the metal plating layer 52b are formed, and also the second interlayer insulating layer 32 is formed to the side of the second metal posts 52 such that the upper surfaces of the second metal posts 52 are exposed.

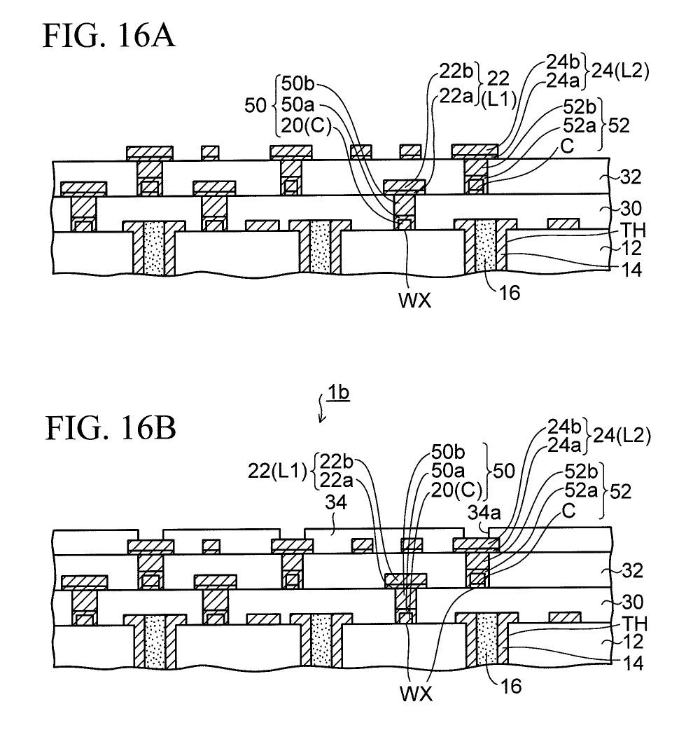

Then, as shown in FIG. 16A, the third wiring layer 24 constructed by the seed layer 24a and the metal plating layer 24b are formed on the second interlayer insulating layer 32 by the semi-additive process. The third wiring layer 24 is arranged on the first metal post 50 and is formed to contain the land L2 whose diameter is larger than the first metal post 50.

Here, in the third embodiment, the stack via can be formed by arranging the second metal post 52 on the land L1 of the second wiring layer 22.

Then, as shown in FIG. 16B, the solder resist 34 in which the opening portions 34a are provided on the lands L2 of the third wiring layer 24 is formed. Then, the contact layer (not shown) is formed by forming the Ni/Au plating layer, or the like on the lands L2 of the third wiring layer 24.

With the above, a wiring substrate 1b of the third embodiment can be obtained. In the third embodiment also, the build-up wiring having the similar wiring structure is formed on the lower surface side of the base wiring plate 10, and the number of stacked layers may be set arbitrarily.

As shown in FIG. 16B and FIG. 17, in the wiring substrate 1b of the third embodiment, out of a pair of first and second wiring layers 20, 22 of the upper and lower sides connected via the first metal post 50 (via conductor), the connection portion of the first wiring layer 20 on the lower side is connected to the first metal post 50 as the landless wiring portion WX whose diameter is equal to the first metal post 50. In contrast, the connection portion of the second wiring layer 22 on the upper side is connected to the first metal post 50 as the land L1 whose diameter is larger than the first metal post 50.

In the third embodiment, the interlayer connection is carried out by providing the first metal post 50 upright to the post connection portion C of the first wiring layer 20 on the lower side by the semi-additive process. Therefore, there is no need to form the land acting as the stopper for the laser processing.

Since such wiring structure is employed, like the first and second embodiments, the width between the metal posts (via conductors) on which the landless wiring portion is arranged can be secured wider than the case where the land is arranged. Therefore, the number of wiring layers arranged between the metal posts (via conductors) can be improved under the same design rule, and as a result a wiring density can be improved in contrast to the related art.

Also, since the land is arranged on the metal post in forming the upper wiring layer, an alignment accuracy of the photolithography can be relaxed. Therefore, the degree of difficulty of process can be lowered, and the multilayer wiring layer can be formed at a low cost with good yield.

In the above first to third embodiments, any wiring layers whose wiring density should be improved among the multilayer wiring layer may be connected to the via conductor with the landless wiring portion, or the wiring layers in which the land is arranged to the upper and lower sides of the via conductor may be contained in the multilayer wiring layer.

What is claimed is:

1. A wiring substrate, comprising:
a first wiring layer;
an insulating layer formed on the first wiring layer;
a via conductor filled to penetrate the insulating layer in a thickness direction, and connected to a connection portion of the first wiring layer; and
a second wiring layer formed on the insulating layer and whose connection portion is connected to the via conductor;
wherein, out of the first wiring layer and the second wiring layer, the connection portion of one wiring layer is formed as a land whose diameter is larger than a diameter of the via conductor, and the connection portion of other wiring layer is formed as a landless wiring portion whose diameter is equal to or smaller than a diameter of the via conductor.

2. A wiring substrate according to claim 1, wherein the connection portion of the first wiring layer is formed as the land, and the connection portion of the second wiring layer is formed as the landless wiring portion, and
the second wiring layer further includes a land whose diameter is larger than the via conductor, to carry out an interlayer connection to an upper wiring layer, on the insulating layer.

3. A wiring substrate according to claim 1, wherein the connection portion of the first wiring layer is formed as the landless wiring portion whose diameter is equal to the via conductor, and the connection portion of the second wiring layer is formed as the land, and
the second wiring layer further includes a connection portion whose diameter is equal to or smaller than the via conductor, to carry out an interlayer connection to an upper wiring layer, on the insulating layer.

4. A method of manufacturing a wiring substrate, comprising the steps of:
forming an insulating layer on a first wiring layer having a land;
forming a via hole which has a diameter smaller than the land and reaches the land, by processing the insulating layer by means of a laser; and
forming a second wiring layer which has a landless wiring portion whose diameter is equal to the via hole, the landless wiring portion arranged on a via conductor filling the via hole, on the insulating layer.

5. A method of manufacturing a wiring substrate, according to claim 4, wherein, the step of forming the second wiring layer includes the steps of:
after the step of forming the via hole,
forming a seed layer on the insulating layer and in the via hole,
forming a plating resist in which an opening portion is provided in a portion where the second wiring layer is arranged,
forming a metal plating layer from an inside of the via hole to an opening portion of the plating resist, by an electroplating utilizing the seed layer as a plating power feeding path,
removing the plating resist, and
etching the seed layer.

6. A method of manufacturing a wiring substrate, comprising the steps of:
providing upright a metal post whose diameter is smaller than a land of a first wiring layer, on the land of a first wiring layer;
forming an insulating layer in which the metal post is embedded;
grinding the insulating layer to expose an upper surface of the metal post and leave the insulating layer on a side of the metal post; and
forming a second wiring layer which has a landless wiring portion whose diameter is equal to or smaller than the metal post, the landless wiring portion arranged on the metal post, on the insulating layer.

7. A method of manufacturing a wiring substrate, according to any one of claims 4 to 6, wherein, in the step of forming the second wiring layer, the second wiring layer is formed to further include a land whose diameter is larger than the via conductor, on the insulating layer, to carry out an interlayer connection to an upper wiring layer.

8. A method of manufacturing a wiring substrate, comprising the steps of:
providing upright a metal post whose diameter is equal to or larger than a connection portion of a first wiring layer, on the connection portion of the first wiring layer;
forming an insulating layer in which the metal post is embedded;
grinding the insulating layer to expose an upper surface of the metal post and leave the insulating layer on a side of the metal post; and
forming a second wiring layer which has a land whose diameter is larger than the metal post, the land arranged on the metal post, on the insulating layer.

9. A method of manufacturing a wiring substrate, according to claim 6, wherein the step of providing upright the metal post includes the steps of:
forming a seed layer on the first wiring layer and the insulating layer,
forming a plating resist, in which an opening portion is provided in a portion where the metal post is arranged, on the seed layer,
forming a metal plating layer in the opening portion of the plating resist, by an electroplating utilizing the seed layer as a plating power feeding path,
removing the plating resist, and
obtaining the metal post by etching the seed layer.

10. A method of manufacturing a wiring substrate, according to claim 8, wherein, in the step of forming the second wiring layer, the second wiring layer is formed to further include a connection portion whose diameter is equal to or smaller than the via conductor, to carry out an interlayer connection to an upper wiring layer, on the insulating layer.
